(19) United States
(12) Patent Application Publication
(10) Pub. No.: US 2024/0333018 A1
(43) Pub. Date: Oct. 3, 2024

(54) ENERGY RECOVERY APPARATUS AND ELECTRONIC DEVICE

(71) Applicant: ZHUHAI COSMX POWER CO., LTD., Zhuhai (CN)

(72) Inventors: Yaxiong DUAN, Zhuhai (CN); Zihao LUO, Zhuhai (CN); Lujia YU, Zhuhai (CN)

(21) Appl. No.: 18/733,786

(22) Filed: Jun. 4, 2024

Related U.S. Application Data
(63) Continuation of application No. PCT/CN2023/085911, filed on Apr. 3, 2023.

(30) Foreign Application Priority Data
Jun. 30, 2022 (CN) 202221694641.8

(51) Int. Cl. H02J 7/06; H01M 10/64; H02J 7/00; H10N 10/10; H10N 10/85

(52) U.S. Cl. CPC H02J 7/06; H01M 10/64; H02J 7/00302; H10N 10/10; H10N 10/85

(57) ABSTRACT

Provided in the present application are an energy recovery apparatus and an electronic device. The energy recovery apparatus includes a thermoelectric conversion unit, a heat dissipation component, a power storage unit, and a heating unit, where the thermoelectric conversion unit includes a first thermoelectric material and a second thermoelectric material, a first end of the first thermoelectric material is connected to a first end of the second thermoelectric material, and the first end of the first thermoelectric material and the first end of the second thermoelectric material are in contact with the heating unit; the heat dissipation component includes a heat pipe, the heat pipe includes a first end and a second end, and the second end of the heat pipe is in contact with a second end of the first thermoelectric material and a second end of the second thermoelectric material.

### CROSS-REFERENCE TO RELATED APPLICATION

This application is a continuation of International Application No. PCT/CN2023/085911, filed on Apr. 3, 2023, which claims priority to Chinese Patent Application No. 202221694641.8, filed with China National Intellectual Property Administration on Jun. 30, 2022. Both of the aforementioned applications are hereby incorporated by reference in their entireties.

### TECHNICAL FIELD

The present application relates to the technical field of batteries, and in particular to an energy recovery apparatus and an electronic device.

### BACKGROUND

Electronic devices generate heat during operation, for example, laptops generate high heat at positions such as processors and graphics cards, and temperature often has a significant impact on the service life of electronic devices. Therefore, heat dissipation measures need to be taken to reduce the temperature of electronic devices during operation. At present, cooling is mainly achieved by dissipating heat into the external environment through fans. However, as the workload increases, the heat production increases significantly, and heat that needs to be discharged to the outside also increases accordingly, resulting in significant energy waste and lower energy utilization efficiency.

### SUMMARY

The present application provides an energy recovery apparatus and an electronic device to solve the problem of low energy utilization efficiency.

In a first aspect, an embodiment of the present application provides an energy recovery apparatus, including a thermoelectric conversion unit, a heat dissipation component, a power storage unit, and a heating unit, the thermoelectric conversion unit includes a first thermoelectric material and a second thermoelectric material, a first end of the first thermoelectric material is connected to a first end of the second thermoelectric material, and the first end of the first thermoelectric material and the first end of the second thermoelectric material are in contact with the heating unit;
the heat dissipation component includes a heat pipe, the heat pipe includes a first end and a second end, and the second end of the heat pipe is in contact with a second end of the first thermoelectric material and a second end of the second thermoelectric material;
the second end of the first thermoelectric material is connected to a first end of the power storage unit, and the second end of the second thermoelectric material is connected to a second end of the power storage unit.

In a second aspect, an embodiment of the present application provides an electronic device, including the energy recovery apparatus discloses in the first aspect of the present application, and the heating unit includes an image processor and/or a central processing unit.

In embodiments of the present application, heat generated by the heating unit is conducted to the first end of the first thermoelectric material and the first end of the second thermoelectric material, making the first end of the first thermoelectric material and the first end of the second thermoelectric material become high-temperature ends. The second end of the first thermoelectric material and the second end of the second thermoelectric material are in contact with the second end of the heat pipe, so that heat of the heating unit is conducted to the first end of the heat pipe, and is dissipated from the second end of the first thermoelectric material and the second end of the second thermoelectric material by the heat dissipation component. Therefore, the second end of the first thermoelectric material and the second end of the second thermoelectric material become low-temperature ends. Thermal energy is transmitted from the high-temperature ends to the low-temperature ends and dissipated through the heat dissipation component. At the same time, the second end of the first thermoelectric material is electrically connected to the first end of the power storage unit, the second end of the second thermoelectric material is electrically connected to the second end of the power storage unit. The conversion of thermal energy to electrical energy can be achieved by using the Seebeck effect, that is, the heat generated during the operation of the heating unit is used to generate electrical energy, which is stored through the power storage unit, thereby improving energy utilization efficiency and reducing energy waste.

### BRIEF DESCRIPTION OF DRAWINGS

To describe the technical solutions of the present application more clearly, the following briefly introduces the accompanying drawings needed for describing the embodiments or the prior art. Apparently, the accompanying drawings in the following description illustrate merely some embodiments of the present application, and persons of ordinary skill in the art may still derive other drawings from these accompanying drawings without creative effort.

FIG. 1 is a first structural schematic diagram of an energy recovery apparatus provided by an embodiment of the present application.

FIG. 2 is a first structural schematic diagram of a thermoelectric conversion unit provided by an embodiment of the present application.

FIG. 3 is a second structural schematic diagram of a thermoelectric conversion unit provided by an embodiment of the present application.

FIG. 4 is a structural schematic diagram of a heat dissipation component provided by an embodiment of the present application.

FIG. 5 is a second structural schematic diagram of an energy recovery apparatus provided by an embodiment of the present application.

### DESCRIPTION OF EMBODIMENTS

The following will describe the technical solutions in embodiments of the present application clearly and completely with reference to the accompanying drawings in embodiments of the present application. Apparently, the described embodiments are a part rather than all embodiments of the present application. Based on embodiments in the present application, all other embodiments obtained by persons of ordinary skill in the art without creative effort shall fall within the protection scope of the present application.

The terms “first”, “second” and so on in embodiments of the present application are used to distinguish similar objects, and are not necessarily used to describe a specific order or precedence. Furthermore, the terms “including” and “having” and any variations thereof are intended to cover non-exclusive inclusion, for example, a process, method, system, product or device that includes a series of steps or units is not necessarily limited to those clearly listed steps or units, but may include other steps or units that are not clearly listed or inherent to such process, method, product or device. Furthermore, “and/or” is used to represent at least one of the connected objects in the present application, such as “A and/or B and/or C” represents 7 cases which are the presence of only A, only B, only C, both A and B, both B and C, both A and C, as well as all of A, B, and C.

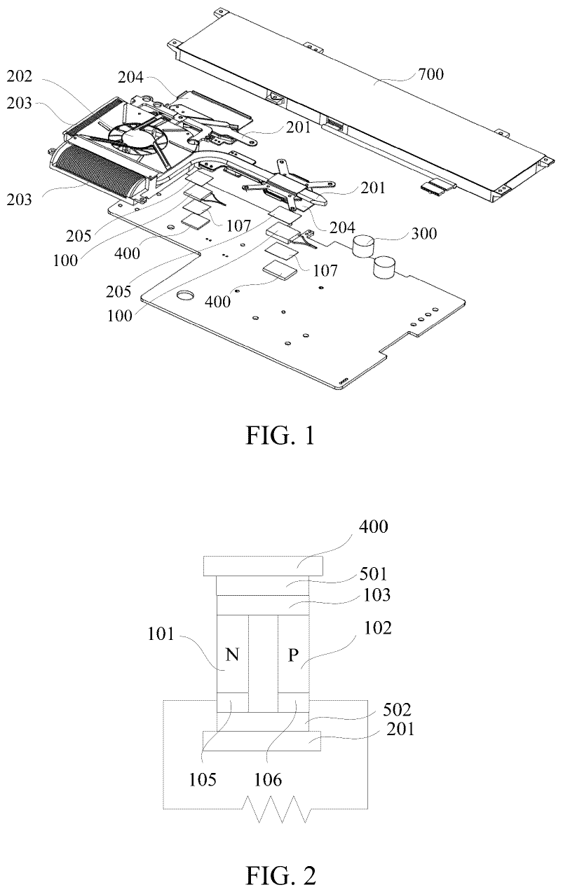

Please refer to FIGS. 1 to 5, embodiments of the present application provide an energy recovery apparatus, including a thermoelectric conversion unit 100, a heat dissipation component 200, a power storage unit 300, and a heating unit 400. The thermoelectric conversion unit 100 includes a first thermoelectric material 101 and a second thermoelectric material 102, a first end of the first thermoelectric material 101 is electrically connected to a first end of the second thermoelectric material 102, and the first end of the first thermoelectric material 101 and the first end of the second thermoelectric material 102 are in contact with the heating unit 400.

The heat dissipation component 200 includes a heat pipe 201, the heat pipe 201 includes a first end and a second end, the second end of the heat pipe 201 is in contact with a second end of the first thermoelectric material 101 and a second end of the second thermoelectric material 102. The second end of the first thermoelectric material 101 is connected to a first end of the power storage unit 300, and the second end of the second thermoelectric material 102 is connected to a second end of the power storage unit 300.

During the heating process of the heating unit 400, heat generated is conducted to the first end of the first thermoelectric material 101 and the first end of the second thermoelectric material 102 in the thermoelectric conversion unit 100, and then conducted to the second end of the first thermoelectric material 101 and the second end of the second thermoelectric material 102. At the same time, the second end of the first thermoelectric material 101 and the second end of the second thermoelectric material 102 are in contact with the second end of the heat pipe 201, and the heat is conducted to the first end of the heat pipe 201 through the heat pipe 201.

In an embodiment, the heat dissipation component further includes a fan 202 and heat dissipation fins 203. The first end of the heat pipe 201 is provided within the heat dissipation fins 203, and the heat dissipation fins 203 are provided at an air outlet of the fan 202, so that heat can be discharged to the outside through the heat dissipation fins 203 and the fan 202.

It should be understood that the first end of the heat pipe 201 is a condensation end, and the second end of the heat pipe 201 is an evaporation end. Heat is conducted from the evaporation end to the condensation end through the heat pipe 201, thereby achieving heat dissipation.

In addition, the first end of the first thermoelectric material 101 and the first end of the second thermoelectric material 102 are in contact with the heating unit 400, resulting in a higher temperature of them, while the second end of the first thermoelectric material 101 and the second end of the second thermoelectric material 102 are in contact with the second end of the heat pipe 201, resulting in a lower temperature of them. That is, in the thermoelectric conversion unit 100, the first end of the first thermoelectric material 101 and the first end of the second thermoelectric material 102 can serve as hot ends of the thermoelectric conversion unit 100, and the second end of the first thermoelectric material 101 and the second end of the second thermoelectric material 102 can serve as cold ends of the thermoelectric conversion unit 100, thereby converting thermal energy into electrical energy by the Seebeck effect.

That is, a part of heat generated by the heating unit 400 is conducted to the outside for heat dissipation through the thermoelectric conversion unit 100, the heat pipe 201, the heat dissipation fins 203, and the fan 202, while the other part of heat is converted into electrical energy through the thermoelectric conversion unit 100 and stored in the power storage unit 300 for heat dissipation.

Specifically, as shown in FIG. 2, in the thermoelectric conversion unit 100, the first thermoelectric material 101 can be understood as a P-type thermoelectric material, and the second thermoelectric material 102 can be understood as an N-type thermoelectric material. With the Seebeck effect, one ends of the P-type and N-type thermoelectric materials can be connected to form a PN junction, and the one ends of the P-type and N-type thermoelectric materials, which are connected, are in a high-temperature state, and the other ends of the P-type and N-type thermoelectric materials, which are not unconnected, are in a low-temperature state. It can be understood that due to the effect of thermal excitation, a hole concentration at the high-temperature end of P-type thermoelectric material is higher than that at the low-temperature end, and an electron concentration at the high-temperature end of N-type thermoelectric material is higher than that at the low-temperature end. That is to say, there is a concentration gradient at both ends of the P-type thermoelectric material and both ends of the N-type thermoelectric material, respectively, causing holes and electrons at the high-temperature ends to be diffused towards the low-temperature ends, resulting in an electromotive force, thereby achieving a conversion of thermal energy to electrical energy through a temperature difference between the hot ends and the cold ends of respective thermoelectric materials. Where the P-type thermoelectric material and the N-type thermoelectric material are semiconductor materials.

Specifically, the first end of the first thermoelectric material 101 and the first end of the second thermoelectric material 102 are indirectly in contact with the heating unit 400. For example, in a PN junction, as shown in FIG. 2, the first end of the first thermoelectric material 101 and the first end of the second thermoelectric material 102 can be electrically connected to a first conductor 103. A surface, which is used for contacting the heating unit 400, of the first conductor 103 is provided with a first thermal conductor 501. For example, the surface, which is used for contacting the heating unit 400, of the first conductor 103 is coated with ceramic, and thus the first conductor 103 is in contact with the heating unit 400 through the ceramic. Heat is conducted through the first conductor 103 to the first end of the first thermoelectric material 101 and the first end of the second thermoelectric material 102, causing them to maintain a high temperature state during the heat dissipation of the heating unit 400, and the first thermal conductor 501 is non-conductive. It can be understood that the cold ends of the thermoelectric conversion unit 100 can also be provided with corresponding configuration, which is not repeated here.

In an embodiment, the energy recovery apparatus includes a plurality of thermoelectric conversion units 100, and the second thermoelectric material 102 of each thermoelectric conversion unit 100 is connected to the first thermoelectric material 101 of its adjacent thermoelectric conversion unit 100 through a fourth conductor 104.

Specifically, the thermoelectric conversion unit 100 can be understood as a PN junction. In embodiments of the present application, a plurality of PN junctions are connected in series and located in adjacent PN junctions. One end of the P-type thermoelectric material in one PN junction can be electrically connected to one end of the N-type thermoelectric material in another adjacent PN junction. In this way, by connecting the plurality of PN junctions in series to form the plurality of thermoelectric conversion units 100, a voltage between the high-temperature ends and the low-temperature ends of each thermoelectric conversion unit 100 can be increased.

In an embodiment, the first end of the first thermoelectric material 101 is connected to the first end of the second thermoelectric material 102 through a first surface of the first conductor 103. A second surface of the first conductor 103 opposite to the first surface thereof is provided with the first thermal conductor 501, and the first thermal conductor 501 is in contact with the heating unit 400; and/or
the second end of the first thermoelectric material 101 is connected to a first surface of a second conductor 105, and a second thermal conductor 502 is provided between a second surface of the second conductor 105 opposite to the first surface thereof and the second end of the heat pipe 201. The second thermal conductor 502 is in contact with the second end of the heat pipe 201; and/or
the second end of the second thermoelectric material 102 is connected to a first surface of a third conductor 106, and the second thermal conductor 502 is provided between a second surface of the third conductor 106 opposite to the first surface thereof and the second end of the heat pipe 201.

As shown in FIG. 2, in the case where the thermoelectric conversion unit 100 includes one PN junction, the first thermoelectric material 101 and the second thermoelectric material 102 can respectively form N-type semiconductor and P-type semiconductor in the PN junction. The first end of the first thermoelectric material 101 can be electrically connected with the first end of the second thermoelectric material 102 through the first conductor 103. Similarly, the first conductor 103, the second conductor 105, and the third conductor 106 can be metal sheets with good thermal conductivity, such as copper sheets.

Where the first thermal conductor 501 and the second thermal conductor 502 can be insulating materials, such as ceramics. The first thermal conductor 501 is used to conduct heat generated by the heating unit 400 to the thermoelectric conversion unit 100, and the second thermal conductor 502 is used to conduct heat of the thermoelectric conversion unit 100 to the heat pipe 201, so that heat can be discharged to the outside by using the heat dissipation fins 203 and the fan 202.

The second end of the first thermoelectric material 101 can also be electrically connected to the second conductor 105, and then the second conductor 105 is in contact with the second end of the heat pipe 201 through the second thermal conductor 502 provided on the first surface of the second conductor 105. Similarly, the second end of the second thermoelectric material 102 can also be electrically connected to the third conductor 106, and then the third conductor 106 is in contact with the second end of the heat pipe through the second thermal conductor 502 provided on the first surface of the second conductor 106.

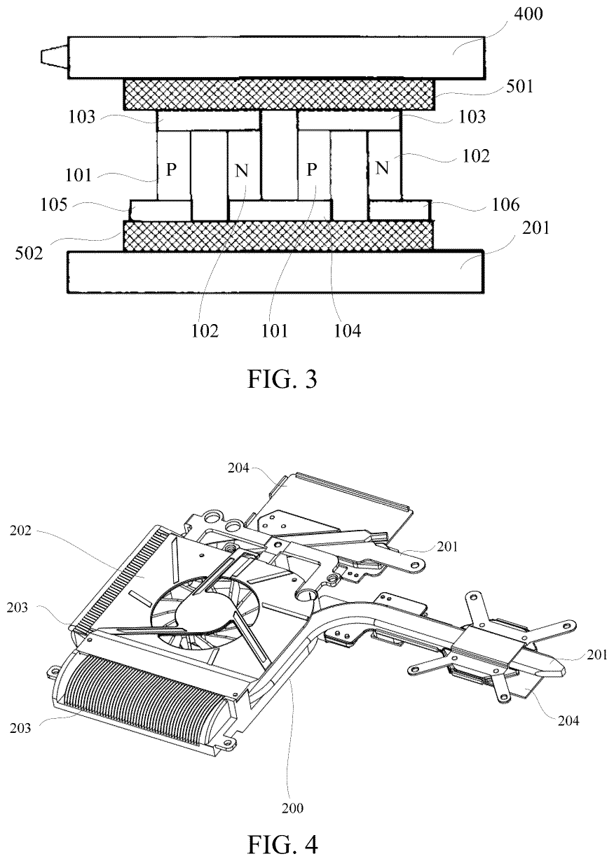

As shown in FIG. 3, in the case where two PN junctions are included, in each PN junction, the second end of the first thermoelectric material 101 is electrically connected to the first surface of the second conductor 105. The second surface of the second conductor 105 is provided with the second thermal conductor 502, the second conductor 105 is in contract with the second end of the heat pipe 201 through the second thermal conductor 502. The first end of the first thermoelectric material 101 is electrically connected to the first end of the second thermoelectric material 102 through the first surface of the first conductor 103, and the second surface of the first conductor 103 is provided with the first thermal conductor 501, and the first conductor 103 is in contact with the heating unit 400 through the first thermal conductor 501. PN junctions can be electrically connected through conductors therebetween, and the second end of the second thermoelectric material 102 is electrically connected to the second end of the first thermoelectric material 101 in an adjacent PN junction through a first surface of the fourth conductor 104, a second surface of the fourth conductor 104 is provided with the second thermal conductor 502, and the fourth conductor 104 is in contact with the second end of the heat pipe 201 through the second thermal conductor 502.

It can be understood that for thermoelectric materials located at both ends of a plurality of thermoelectric conversion units 100, one ends of the thermoelectric materials near the heat pipe 201 can also be electrically connected to conductors, respectively. For example, in FIG. 3, the second end of the first thermoelectric material 101 located at one end of the two PN junctions is electrically connected to the second conductor 105, and the second end of the second thermoelectric material 102 located at the other end of the two PN junctions is electrically connected to the third conductor 106. Both the second conductor 105 and the third conductor 106 are provided with the second thermal conductor 502, the second conductor 105 and the third conductor 106 can be in contact with the heat pipe 201 through the second thermal conductor 502.

In the case where the thermoelectric conversion unit 100 includes two or more PN junctions, respective PN junctions are sequentially connected in series, and the specific connection can refer to the above implementation method.

In the thermoelectric conversion unit 100, a PN junction is used to achieve thermoelectric conversion. It can be understood that a single PN junction can generate a smaller electromotive force. Therefore, in embodiments of the present application, a plurality of PN junctions can be connected to form a plurality of thermoelectric conversion units 100 to obtain a larger voltage. Where the heating unit 400 can be any component that generates heat, such as a Central Processing Unit (CPU), Graphics Processing Unit (GPU), or other electronic components that generate more heat during operation in electronic devices.

It should be noted that if there are two or more heating units 400 in an electronic device, a set of thermoelectric conversion units 100 is provided for each heating unit 400, and one ends of respective thermoelectric conversion units 100 can abut against a first end of the heat dissipation component 200 to form low-temperature ends, thereby achieving heat dissipation of the two or more heating units 400. In addition, electrical energy generated by heat conversion of the two or more heating units 400 can be stored in the same power storage unit 300 to avoid the situation where a single heating unit 400 produces less heat and has less electrical energy storage, and to reduce costs.

Where the power storage unit 300 can include one or more capacitors. In a case where the first thermoelectric material is a P-type thermoelectric material and the second thermoelectric material is an N-type thermoelectric material for an example, holes in the first thermoelectric material diffuse from the first end to the second end, and electrons in the second thermoelectric material diffuse from the first end to the second end. Two ends of the power storage unit 300 are respectively connected to the second end of the first thermoelectric material and the second end of the second thermoelectric material, thereby forming a charging loop.

In embodiments of the present application, heat generated by the heating unit 400 is conducted to the first end of the first thermoelectric material 101 and the first end of the second thermoelectric material 102, making the first end of the first thermoelectric material 101 and the first end of the second thermoelectric material 102 become high-temperature ends. The second end of the first thermoelectric material 101 and the second end of the second thermoelectric material 102 are in contact with the second end of the heat pipe 201, so that heat of the heating unit 400 is conducted to the first end of the heat pipe 200, thereby achieving heat dissipation of the second end of the first thermoelectric material 101 and the second end of the second thermoelectric material 102 through the heat dissipation component 200, making the second end of the first thermoelectric material 101 and the second end of the second thermoelectric material 102 become low-temperature ends. Thermal energy is conducted from the high-temperature ends to the low-temperature ends and dissipated through the heat dissipation component 200. At the same time, the second end of the first thermoelectric material 101 is electrically connected to the first end of the power storage unit 300, and the second end of the second thermoelectric material 102 is electrically connected to the second end of the power storage unit 300. The converting of thermal energy into electrical energy is achieved by using the Seebeck effect. That is, heat generated during the operation of the heating unit 400 is generated to electric energy, then the electric energy is stored in the power storage unit 300, thereby improving energy utilization efficiency and reducing energy waste.

Moreover, for the heat generated during the operation of the heating unit 400, the heat that originally needed to be discharged to the outside is partly converted into electrical energy through the energy recovery apparatus, reducing heat that needs to be dissipated. The heat that has not been converted into electrical energy can be discharged to the outside through the heat dissipation component 200, thereby improving the heat dissipation effect.

In an embodiment, the second end of the heat pipe 201 is provided with a thermal conductive sheet 204, the heat pipe 201 is in contact with the second end of the first thermoelectric material 101 and the second end of the second thermoelectric material 102 through the thermal conductive sheet 204.

Where the second end of the first thermoelectric material 101 and the second end of the second thermoelectric material 102 achieve heat dissipation and cooling through the heat pipe 201, the fan 202, and the heat dissipation fins 203, forming a temperature difference with a high temperature generated by a heat source contacting with the first end of the first thermoelectric material 101 and the first end of the second thermoelectric material 102, thereby improving the thermoelectric conversion efficiency of the thermoelectric conversion unit 100.

Where the thermal conductive sheet 204 can also be made of a material with good thermal conductivity, and in order to improve the thermal conductivity effect, the shape of the thermal conductive sheet 204 can be set to match the shape of the thermoelectric conversion unit 100. For example, as shown in FIG. 1, the thermal conductive sheet 204 is provided with a sheet shape so as to be attached to the second end of the first thermoelectric material 101 and the second end of the second thermoelectric material 102, thereby increasing a contact area. Heat from the second end of the first thermoelectric material 101 and the second end of the second thermoelectric material 102 is conducted through the heat pipe 201 to an air outlet of the fan 202. Specifically, the fan 202 can be a centrifugal fan, which discharges the heat of the second end of the first thermoelectric material 101 and the second end of the second thermoelectric material 102 to make the second end of the first thermoelectric material 101 and the second end of the second thermoelectric material 102 form low-temperature ends.

It can be understood that the thermal conductivity efficiency of the heat pipe 201 is good. Heat is conducted to the second end of the heat pipe 201 through the thermal conductive sheet 204, and the heat of the first end of the heat pipe 201 is discharged through the heat dissipation component 200. This can make the second end of the first thermoelectric material 101 and the second end of the second thermoelectric material 102 maintain a relatively low temperature. In this way, heat generated by the heating unit 400 can be partly converted into electrical energy, and heat dissipation can be achieved through the conversion of thermal energy and heat discharge.

In an embodiment, as shown in FIG. 2, a first surface of the thermal conductive sheet 204 is coated with a first thermal conductive material 205, and the first surface of the thermal conductive sheet 204 is a surface of the thermal conductive sheet 204 facing the second end of the first thermoelectric material 101 and the second end of the second thermoelectric material 102;
and/or
a surface of the heating unit 400 is coated with a second thermal conductive material 107.

Where the thermoelectric conversion unit 100 includes the first conductor 103, the second conductor 105 and the third conductor 106. The hot end of the thermoelectric conversion unit 100 is provided with the first thermal conductor 501, and the cold end of the thermoelectric conversion unit 100 is provided with the second thermal conductor 502. It can be understood that the hot end of the thermoelectric conversion unit 100 is the end that is in contract with the heating unit 400, and the cold end of the thermoelectric conversion unit 100 is the end that is in contract with the heat pipe 201. That is, the first end of the first thermoelectric material 101 is electrically connected with the first end of the second thermoelectric material 102 through the first conductor 103, the first conductor 103 is in contract with the heating unit 400 through the first thermal conductor 501, and the second end of the first thermoelectric material 101 is electrically connected with the second conductor 105, the second conductor 105 is in contract with the second end of the heat pipe 201 through the second thermal conductor 502. The second end of the second thermoelectric material 102 is electrically connected with the third conductor 106, and the third conductor 106 is in contact with the second end of the heat pipe 201 through the second thermal conductor 502, and the heat pipe 201 can discharge heat through the heat dissipation fins 203 and the fan 202. So that the first end of the first thermoelectric material 101 is a high-temperature end relative to the second end of the first thermoelectric material 101, and the first end of the second thermoelectric material 102 is a high-temperature end relative to the second end of the second thermoelectric material 102.

The first thermal conductor 501 can be made of a material with good thermal conductivity, and in order to improve the thermal conductivity effect, the shape of the first thermal conductor 501 can be set to match the shape of the heating unit 400, for example, it can be set to a sheet shape to attach to the surface of the heating unit 400.

Moreover, the surface of the thermal conductive sheet 204 can be coated with a first thermal conductive material (such as heat-conducting silicone grease) to reduce a contact thermal resistance, and a specific coating position can be a portion of the thermal conductive sheet 204 which is in contact with the second end of the first thermoelectric material 101 and the second end of the second thermoelectric material 102. In an embodiment, a coating thickness of the first thermal conductive material can be less than 0.05 mm, and a thermal conductive material having a thermal conductivity of larger than 3 W/(m·K) is selected for coating to improve the thermal conductivity effect. The surface of the heating unit 400 can be coated with the second thermal conductive material 107, and the reference may be made according to that the heat-conducting sheet 204 is coated with the first thermal conductive material 205, which is not repeated here.

In the energy recovery apparatus, the thermal conductive material can be coated on the surface of at least one of the thermal conductive sheet 204 and the heating unit 400 to improve the thermal conductivity effect. For example, the thermal conductive material can be coated on the first surface of the thermal conductive material sheet 204 or the surface of the heating unit 400 alone, or corresponding thermal conductive materials can be coated on both the first surface of the thermal conductive sheet 204 and the surface of the heating unit 400.

In an embodiment, a thickness of the first thermal conductive material 205 is less than 0.05 mm;
and/or
a thickness of the second thermal conductive material 107 is less than 0.05 mm;
and/or
a thermal conductivity of the first thermal conductive material 205 is larger than 3 W/(m·K);
and/or
a thermal conductivity of the second thermal conductive material 107 is larger than 3 W/(m·K).

It can be understood that the heat dissipation fins 203 can increase a heat conduction area by disposing the first end of the heat pipe 201 within the heat dissipation fins 203 and disposing the heat dissipation fins 203 at the air outlet of the fan 202, that is, the fan 202 can discharge heat from the first end of the heat pipe 201 to the outside. Specifically, the fan 202 can be a centrifugal fan.

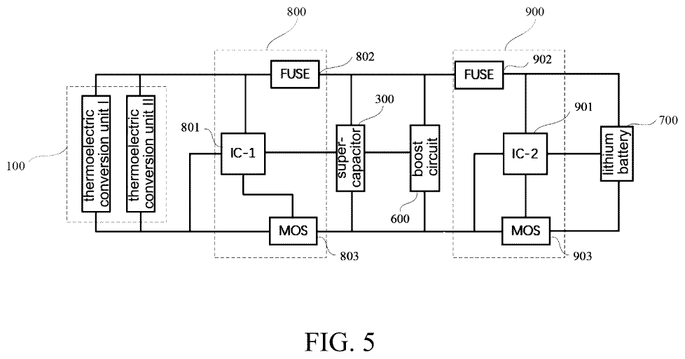

In an embodiment, as shown in FIG. 5, the device further includes a boost circuit 600 and a battery 700. The first end of the power storage unit 300 is electrically connected to a first end of the boost circuit 600, the second end of the power storage unit 300 is electrically connected to a second end of the boost circuit 600, a third end of the power storage unit 300 is electrically connected to a third end of the boost circuit 600. The first end of the boost circuit 600 is electrically connected to a positive pole of the battery 700, and the second end of the boost circuit 600 is electrically connected to a negative pole of the battery 700.

Specifically, the power storage unit 300 can be a super-capacitor to store electrical energy, and when a voltage of the battery to be charged is higher than a voltage of the super-capacitor, the charging of the battery 700 can be achieved by boosting the voltage through the boost circuit 600. In addition, the battery 700 and the heating unit 400 can be located in a same electronic device, so that heat generated by the heat source inside the electronic device can be used to charge the battery 700 of the electronic device through the energy recovery apparatus, thereby improving energy utilization efficiency.

In an embodiment, as shown in FIG. 5, the device further includes a first charging protection circuit 800, the second end of the first thermoelectric material is electrically connected to a first end of the first charging protection circuit 800, and a second end of the first charging protection circuit 800 is electrically connected to the first end of the power storage unit 300, the second end of the power storage unit 300 is electrically connected to a third end of the first charging protection circuit 800, and a fourth end of the first charging protection circuit 800 is electrically connected to the second end of the second thermoelectric material;
and/or
the device further includes a second charging protection circuit 900, the first end of the boost circuit 600 is electrically connected to a first end of the second charging protection circuit 900, the second end of the boost circuit 600 is electrically connected to a second end of the second charging protection circuit 900, a third end of the second charging protection circuit 900 is electrically connected to the positive pole of the battery 700, and a fourth end of the second charging protection circuit 900 is electrically connected to the negative pole of the battery 700.

In this implementation, the first charging protection circuit 800 is used to protect a charging loop formed by the second end of the first thermoelectric material, the second end of the second thermoelectric material, and the power storage unit 300, thereby improving the safety of thermoelectric conversion. By providing the second charging protection circuit 900 between the boost circuit 600 and the battery 700, the charging of the battery 700 is protected and the charging safety is improved.

In an embodiment, as shown in FIG. 5, the first charging protection circuit 800 includes a first control chip 801, a first fuse 802, and a first metal oxide semiconductor field-effect transistor MOS tube 803. The second end of the first thermoelectric material is electrically connected to a first end of the control chip and a first end of the first fuse 802; a second end of the first fuse 802 is electrically connected to the first end of the power storage unit 300; the second end of the second thermoelectric material is electrically connected to a second end of the first control chip 801 and a source electrode of the first MOS tube 803; a third end of the first control chip 801 is electrically connected to a gate electrode of the first MOS tube 803; a drain electrode of the first MOS tube 803 is electrically connected to the second end of the power storage unit 300; and a fourth end of the first control chip 801 is electrically connected to the third end of the power storage unit 300;

and/or
the second charging protection circuit 900 includes a second control chip 91, a second fuse 902, and a second MOS tube 903; the first end of the boost circuit 600 is electrically connected to a first end of the second fuse 902, and a second end of the second fuse 902 is electrically connected to a first end of the second control chip 901 and the positive pole of the battery 700; the second end of the boost circuit 600 is electrically connected to a second end of the second control chip 901 and a source electrode of the second MOS tube 903; a third end of the second control chip 901 is electrically connected to a gate electrode of the second MOS tube 903, and a drain electrode of the second MOS tube 903 is electrically connected to the negative pole of the battery 700, a fourth end of the second control chip 901 is electrically connected to a controlled end of the battery 700.

Where the charging loop can be monitored through the first control chip 901, excessive current of the loop can be prevented through the first fuse 902, and excessive voltage can be prevented through the first MOS tube 903, thereby achieving charging protection for the charging loop.

Embodiments in the present application further provide an electronic device, including the energy recovery apparatus described above, and the heating unit includes an image processor and/or a central processing unit. It should be noted that the electronic device provided in embodiments of the present application includes all technical features of embodiments of the energy recovery apparatus described above, which can achieve the same technical effects. To avoid repetition, it will not be repeated here.

For the convenience of understanding, in FIG. 1, two heating units 400 are respectively used as CPU and GPU in a laptop computer for an example. The CPU and GPU are both disposed on a motherboard, and thermoelectric conversion units 100 are respectively disposed above the CPU and GPU. Each thermoelectric conversion unit 100 obtains heat of each heating unit 400 through the first thermal conductive material coated on the surface of the first conductor, that is, a contact end between the thermoelectric conversion unit 100 and the heating unit 400 in FIG. 1 forms a high-temperature end. The thermoelectric conversion unit 100 conducts heat to the heat pipe 201 through the second thermal conductive material 601 coated on the surface of the thermal conductive sheet 204 as well as the thermal conductive sheet 204, and then the heat is discharged to the outside through the heat pipe 201 and the heat dissipation component 200, that is, a contact end between the thermoelectric conversion unit 100 and the second thermal conductive material 204 forms a low-temperature end. At the same time, the high-temperature end and the low-temperature end of the thermoelectric conversion unit 100 are electrically connected to the power storage unit 300 through positive and negative wires, so that electric energy generated by the conversion of the thermoelectric conversion unit 100 can be used to charge the power storage unit 300, thereby achieving heat dissipation by converting this part of thermal energy into electrical energy.

In this embodiment, electric energy stored in the power storage unit 300 can also charge the battery 700 of the electronic device. For example, when a minimum charging voltage of the battery 700 is larger than a voltage of the power storage unit 300, the boost circuit 600 can be set between the power storage unit 300 and the battery 700 to charge the battery 700, which increases the battery life of the electronic device, and save electricity. Specifically, the boost circuit 600 can be achieved through a power amplifier tube.

In addition, a charging protection circuit can be set between the power storage unit 300 and the boost circuit 600, as well as between the boost circuit 600 and the battery 700, to prevent overcharging and overvoltage, and to control the charging process, thereby improving the safety of charging.

Where the electronic device can be terminal devices such as, mobile phone, Tablet Personal Computer, Laptop Computer (also known as notebook computer), Personal Digital Assistant (PDA), handheld computer, netbook, Ultra-Mobile Personal Computer (UMPC), Mobile Internet Device (MID), Wearable Devices or Vehicle User Equipment (VUE), Pedestrian User Equipment (PUE), etc. The wearable devices include: smart-watches, wristbands, headphones, glasses, etc. It should be noted that in embodiments of the present application, the specific types of the electronic device are not limited.

The foregoing are preferred embodiments of the present application. It should be pointed out that for persons of ordinary skill in the art, a plurality of improvements and modifications can be made without departing from the principle of the present application. These improvements and modifications should also be considered as the scope of protection of the present application.

What is claimed is:

1. An energy recovery apparatus, comprising a thermoelectric conversion unit, a heat dissipation component, a power storage unit, and a heating unit, the thermoelectric conversion unit comprises a first thermoelectric material and a second thermoelectric material, a first end of the first thermoelectric material is electrically connected to a first end of the second thermoelectric material, and the first end of the first thermoelectric material and the first end of the second thermoelectric material are in contact with the heating unit;
the heat dissipation component comprises a heat pipe, the heat pipe comprises a first end and a second end, the second end of the heat pipe is in contact with a second end of the first thermoelectric material and a second end of the second thermoelectric material;
the second end of the first thermoelectric material is connected to a first end of the power storage unit, and the second end of the second thermoelectric material is connected to a second end of the power storage unit.

2. The apparatus according to claim 1, wherein the first end of the first thermoelectric material is connected to the first end of the second thermoelectric material through a first surface of a first conductor, a second surface of the first conductor opposite to the first surface thereof is provided with a first thermal conductor, and the first thermal conductor is in contact with the heating unit; and/or
the second end of the first thermoelectric material is connected to a first surface of a second conductor, and a second thermal conductor is provided between a second surface of the second conductor opposite to the first surface thereof and the second end of the heat pipe; and/or
the second end of the second thermoelectric material is connected to a first surface of a third conductor, and the second thermal conductor is provided between a second surface of the third conductor opposite to the first surface thereof and the second end of the heat pipe.

3. The apparatus according to claim 1, wherein the second end of the heat pipe is provided with a thermal conductive sheet, the heat pipe is in contact with the second end of the first thermoelectric material and the second end of the second thermoelectric material through the thermal conductive sheet.

4. The apparatus according to claim 2, wherein the second end of the heat pipe is provided with a thermal conductive sheet, the heat pipe is in contact with the second end of the first thermoelectric material and the second end of the second thermoelectric material through the thermal conductive sheet.

5. The apparatus according to claim 3, wherein a first surface of the thermal conductive sheet is coated with a first thermal conductive material, and the first surface of the thermal conductive sheet is the surface of the thermal conductive sheet facing the second end of the first thermoelectric material and the second end of the second thermoelectric material;
and/or
a surface of the heating unit is coated with a second thermal conductive material.

6. The apparatus according to claim 4, wherein a first surface of the thermal conductive sheet is coated with a first thermal conductive material, and the first surface of the thermal conductive sheet is the surface of the thermal conductive sheet facing the second end of the first thermoelectric material and the second end of the second thermoelectric material;
and/or
a surface of the heating unit is coated with a second thermal conductive material.

7. The apparatus according to claim 5, wherein a thickness of the first thermal conductive material is less than 0.05 mm;
and/or
a thickness of the second thermal conductive material is less than 0.05 mm;
and/or
a thermal conductivity of the first thermal conductive material is larger than 3 W/(m·K);
and/or
a thermal conductivity of the second thermal conductive material is larger than 3 W/(m·K).

8. The apparatus according to claim 6, wherein a thickness of the first thermal conductive material is less than 0.05 mm;
and/or
a thickness of the second thermal conductive material is less than 0.05 mm;
and/or
a thermal conductivity of the first thermal conductive material is larger than 3 W/(m·K);
and/or
a thermal conductivity of the second thermal conductive material is larger than 3 W/(m·K).

9. The apparatus according to claim 1, wherein the apparatus further comprises a boost circuit and a battery, the first end of the power storage unit is electrically connected to a first end of the boost circuit, the second end of the power storage unit is electrically connected to a second end of the boost circuit, a third end of the power storage unit is electrically connected to a third end of the boost circuit, the first end of the boost circuit is electrically connected to a positive pole of the battery, and the second end of the boost circuit is electrically connected to a negative pole of the battery.

10. The apparatus according to claim 2, wherein the apparatus further comprises a boost circuit and a battery, the first end of the power storage unit is electrically connected to a first end of the boost circuit, the second end of the power storage unit is electrically connected to a second end of the boost circuit, a third end of the power storage unit is electrically connected to a third end of the boost circuit, the first end of the boost circuit is electrically connected to a positive pole of the battery, and the second end of the boost circuit is electrically connected to a negative pole of the battery.

11. The apparatus according to claim 3, wherein the apparatus further comprises a boost circuit and a battery, the first end of the power storage unit is electrically connected to a first end of the boost circuit, the second end of the power storage unit is electrically connected to a second end of the boost circuit, a third end of the power storage unit is electrically connected to a third end of the boost circuit, the first end of the boost circuit is electrically connected to a positive pole of the battery, and the second end of the boost circuit is electrically connected to a negative pole of the battery.

12. The apparatus according to claim 4, wherein the apparatus further comprises a boost circuit and a battery, the first end of the power storage unit is electrically connected to a first end of the boost circuit, the second end of the power storage unit is electrically connected to a second end of the boost circuit, a third end of the power storage unit is electrically connected to a third end of the boost circuit, the first end of the boost circuit is electrically connected to a positive pole of the battery, and the second end of the boost circuit is electrically connected to a negative pole of the battery.

13. The apparatus according to claim 5, wherein the apparatus further comprises a boost circuit and a battery, the first end of the power storage unit is electrically connected to a first end of the boost circuit, the second end of the power storage unit is electrically connected to a second end of the boost circuit, a third end of the power storage unit is electrically connected to a third end of the boost circuit, the first end of the boost circuit is electrically connected to a positive pole of the battery, and the second end of the boost circuit is electrically connected to a negative pole of the battery.

14. The apparatus according to claim 6, wherein the apparatus further comprises a boost circuit and a battery, the first end of the power storage unit is electrically connected to a first end of the boost circuit, the second end of the power storage unit is electrically connected to a second end of the boost circuit, a third end of the power storage unit is electrically connected to a third end of the boost circuit, the first end of the boost circuit is electrically connected to a positive pole of the battery, and the second end of the boost circuit is electrically connected to a negative pole of the battery.

15. The apparatus according to claim 7, wherein the apparatus further comprises a boost circuit and a battery, the first end of the power storage unit is electrically connected to a first end of the boost circuit, the second end of the power storage unit is electrically connected to a second end of the boost circuit, a third end of the power storage unit is electrically connected to a third end of the boost circuit, the first end of the boost circuit is electrically connected to a positive pole of the battery, and the second end of the boost circuit is electrically connected to a negative pole of the battery.

16. The apparatus according to claim 9, wherein the apparatus further comprises a first charging protection circuit, the second end of the first thermoelectric material is electrically connected to a first end of the first charging protection circuit, a second end of the first charging protection circuit is electrically connected to the first end of the power storage unit, the second end of the power storage unit is electrically connected to a third end of the first charging protection circuit, and a fourth end of the first charging protection circuit is electrically connected to the second end of the second thermoelectric material;
and/or
the apparatus further comprises a second charging protection circuit, the first end of the boost circuit is electrically connected to a first end of the second charging protection circuit, the second end of the boost circuit is electrically connected to a second end of the second charging protection circuit, a third end of the second charging protection circuit is electrically connected to the positive pole of the battery, and a fourth end of the second charging protection circuit is electrically connected to the negative pole of the battery.

17. The apparatus according to claim 16, wherein the first charging protection circuit comprises a first control chip, a first fuse, and a first metal oxide semiconductor field-effect transistor MOS tube, the second end of the first thermoelectric material is electrically connected to a first end of the first control chip and a first end of the first fuse, a second end of the first fuse is electrically connected to the first end of the power storage unit, the second end of the second thermoelectric material is electrically connected to a second end of the first control chip and a source electrode of the first MOS tube, a third end of the first control chip is electrically connected to a gate electrode of the first MOS tube, a drain electrode of the first MOS tube is electrically connected to the second end of the power storage unit, and a fourth end of the first control chip is electrically connected to the third end of the power storage unit;
and/or
the second charging protection circuit comprises a second control chip, a second fuse, and a second MOS tube, the first end of the boost circuit is electrically connected to a first end of the second fuse, and a second end of the second fuse is electrically connected to a first end of the second control chip and the positive pole of the battery, the second end of the boost circuit is electrically connected to a second end of the second control chip and a source electrode of the second MOS tube, a third end of the second control chip is electrically connected to a gate electrode of the second MOS tube, and a drain electrode of the second MOS tube is electrically connected to the negative pole of the battery, a fourth end of the second control chip is electrically connected to a controlled end of the battery.

18. The apparatus according to claim 1, wherein the energy recovery apparatus comprises a plurality of thermoelectric conversion units, and the second thermoelectric material of each of the thermoelectric conversion units is connected to the first thermoelectric material of its adjacent thermoelectric conversion unit through a fourth conductor.

19. An electronic device, comprising the energy recovery apparatus according to claim 1, and the heating unit comprises an image processor and/or a central processing unit.
